(19) United States
(12) Patent Application Publication
(10) Pub. No.: US 2009/0142914 A1
(43) Pub. Date: Jun. 4, 2009

(54) Method for Manufacturing Semiconductor Device

(76) Inventor: Chung Kyung JUNG, Anyang-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/273,820

(22) Filed: Nov. 19, 2008

(30) Foreign Application Priority Data
Nov. 30, 2007 (KR) 10-2007-0123566

(51) Int. Cl. H01L 21/3205

(52) U.S. Cl. 438/594; 257/E21.179

(57) ABSTRACT

Disclosed are methods for manufacturing a semiconductor device, capable of inhibiting an undercut from occurring in a dielectric layer formed between a floating gate and a control gate. In one method, the dielectric layer can be protected using a covering of a nitride layer that can be used as a hard mask for gate patterning in a flash memory device. In another method, the gate stack can be inhibited from being damaged by changing the material of the hard mask used to etch the gate stack. For example, an LTO can be used as the hardmask.

### CROSS-REFERENCE TO RELATED APPLICATION

The present application claims the benefit under 35 U.S.C. §119 of Korean Patent Application No. 10-2007-0123566, filed Nov. 30, 2007, which is hereby incorporated by reference in its entirety.

### BACKGROUND

In general, flash memories enable data to be electrically programmed or erased. Two common flash memories include EPROMs (Erasable Programmable Read Only Memories) and EEPROMs (Electrically Erasable PROMs). Ad vantageously, the flash memories can often be manufactured at a low cost due to a simplified manufacturing process and a small chip size thereof.

In addition, although flash memory is a non-volatile semiconductor memory in which data is retained even if power is shut off, flash memory has a characteristic of a RAM (Random Access Memory) in that information can be electrically programmed or erased in a system in an easy manner. Accordingly, flash memory has served as a substitute for a memory card or a hard disk of portable office automation equipment.

In such a flash memory, data programming is achieved through the injection of hot electrons. In detail, if the hot electrons are generated in a channel due to the potential difference between a source and a drain, some of the hot electrons, which have obtained energy of 3.1 eV (the potential barrier between a multi-crystalline silicon layer and an oxide layer forming a gate) or more, are moved into a floating gate and stored therein due to a high electric field applied to a control gate.

FIG. 1 is a cross-sectional view showing a conventional flash memory device.

As shown in FIG. 1, a flash memory device often includes a semiconductor substrate 10 formed thereon with a floating gate 11, a dielectric layer 12, and a control gate 13 in a stack-type gate structure.

The dielectric layer 12 typically includes an ONO (oxide-nitride-oxide) structure. Because of this structure, an undercut (see, reference symbol A) may be formed in the dielectric layer 12 which is exposed when a hard mask including a silicon oxide layer or a silicon nitride layer is removed. Accordingly, the characteristic of the flash memory device may be degraded.

### BRIEF SUMMARY

Embodiments of the present invention provide a method for manufacturing a semiconductor device, capable of inhibiting an undercut from occurring in a dielectric layer. According to an embodiment, the dielectric layer for a floating gate and control gate stack can be covered using a nitride layer as a hard mask when performing a gate patterning process in a flash memory device.

An embodiment of the present invention provides a method for manufacturing a semiconductor device, capable of inhibiting a gate stack from being damaged by changing a material of a hard mask.

According to an embodiment, a method for manufacturing a semiconductor device can include sequentially forming a floating gate layer, a dielectric layer, a control gate layer, and a first hard mask on a semiconductor substrate; forming a control gate and a dielectric layer pattern by etching the control gate layer and the dielectric layer by using the first hard mask as a mask; forming a second hard mask layer on an entire surface of the semiconductor substrate formed with the control gate and the dielectric layer pattern; forming a second hard mask by etching the second hard mask layer, wherein the second hard mask surrounds the control gate and the dielectric layer pattern; and forming a floating gate by etching the floating gate layer using the second hard mask as a mask.

According to another embodiment, a method for manufacturing a semiconductor device can include sequentially forming a floating gate layer, a dielectric layer, and a control gate layer on a semiconductor substrate; forming an LTO layer on the control gate layer, forming a hard mask by patterning the LTO layer; forming a gate stack by etching the control gate layer, the dielectric layer, and the floating gate layer using the hard mask as a mask; and removing the hard mask.

### BRIEF DESCRIPTION OF THE DRAWINGS

FIG. 1 is a cross-sectional view showing a conventional flash memory.

FIGS. 2 to 7 are cross-sectional views showing a method for manufacturing a semiconductor device according to an embodiment of the present invention.

FIGS. 8 to 10 are cross-sectional views showing a method for manufacturing a semiconductor device according to another embodiment of the present invention.

FIG. 11 is a graph showing characteristics of a hard mask according to an embodiment of the present invention.

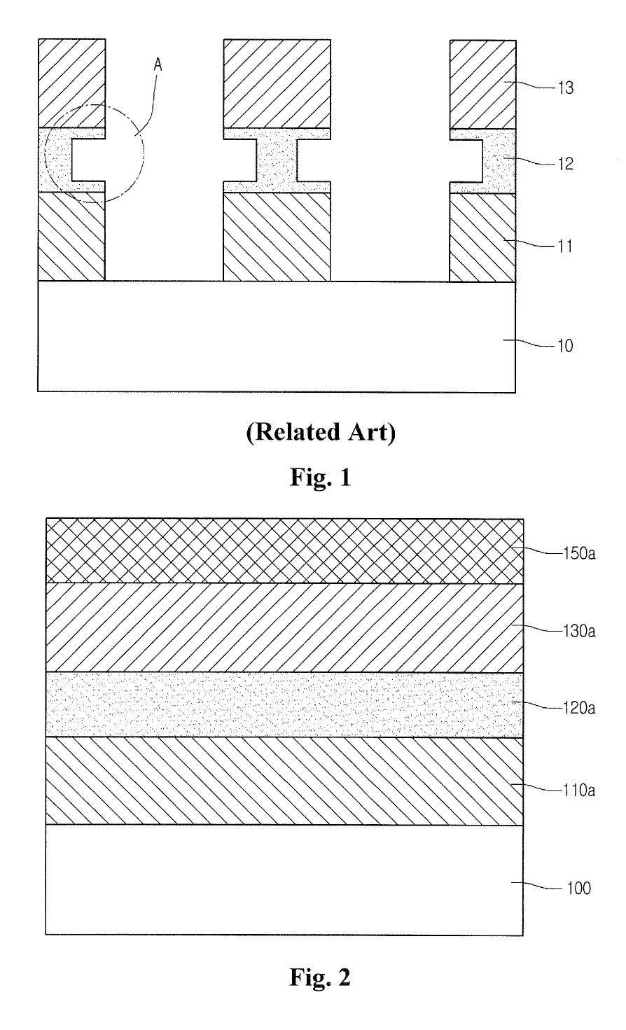

### DETAILED DESCRIPTION

Hereinafter, methods for manufacturing a semiconductor device according to embodiments will be described in detail with reference to accompanying drawings. It should be understood that the examples and embodiments described herein are for illustrative purposes only and that various modifications or changes in light thereof will be suggested to persons skilled in the art and are to be included within the spirit and purview of this application.

The terms “first” and” second” described below are used to distinguish members from each other and to represent at least two members, not to define the members. Accordingly, if the terms “first” and “second” are mentioned, a plurality of members can be provided, and the members can be selectively or alternatively used. The size (dimension) of elements shown in the drawings may be magnified for the purpose of clear explanation and the real size of the elements may be different from the size of elements shown in drawings. In addition, the present invention may not include all the elements shown in the drawings and may not be limited thereto. The elements except for essential elements of the present invention can be omitted or added without limitation.

In the description of an embodiment, it will be understood that when a layer (or film) is referred to as being ‘on/above/over/upper’ another layer or substrate, it can be directly on another layer or substrate, or intervening layers may also be present. Further, it will be understood that when a layer is referred to as being ‘down/below/under/lower’ another layer, it can be directly under another layer, or one or more intervening layers may also be present. In addition, it will also be understood that when a layer is referred to as being ‘between’ two layers, it can be the only layer between the two layers, or one or more intervening layers may also be present. Thus, the meaning thereof must be determined based on the scope of the embodiment. In the following description of the present invention, a detailed description of known functions and configurations incorporated herein will be omitted when it may make the subject matter of the present invention rather unclear.

A method for manufacturing a semiconductor device according to an embodiment will be described with reference to FIGS. 2 to 7.

Referring to FIG. 2, a first polysilicon layer 110a for a floating gate can be formed on an entire surface of a semiconductor substrate 100.

In one embodiment, the first polysilicon layer 110a can be formed through LP-CVD (Low Pressure Chemical Vapor Deposition). According to certain embodiments, the first polysilicon layer 110a can be formed to have a thickness in the range of about 1000 Å to about 5500 Å.

Then, a dielectric layer 120a can be formed on the first polysilicon layer 110a. The dielectric layer 120a can have an oxide-nitride-oxide (ONO) structure.

For example, in an embodiment, the dielectric layer 120a can have the ONO structure by forming an oxide layer having a thickness in the range of about 50 Å to about 70 Å through LP-CVD under a temperature in the range of about 700° C. to about 800° C., a nitride layer having a thickness in the range of 60 Å to 80 Å through LP-CVD under a temperature in the range of about 650° C. to about 750° C., and an oxide layer having a thickness in the range of about 50 Å to about 70 Å through a furnace thermal process (FTP) or LP-CVD under a temperature in the range of about 80° C. to about 900° C.

A second polysilicon layer 130a for a control gate can be formed on the dielectric layer 120a. In one embodiment, the second polysilicon layer 130a can be formed using LP-CVD. In certain embodiments, the second polysilicon layer 130a can be formed to a thickness in the range of about 1000 Å to about 5500 Å.

A first hard mask layer 150a can be formed on the second polysilicon layer 130a.

The first hard mask layer 150a can include an oxide layer.

The first hard mask layer 150a can have a thickness thinner than a thickness of a conventional hard mask layer by twice or more. This is because the second polysilicon layer 130 and the dielectric layer 120a are etched in the subsequent process by using the first hard mask as an etch mask. In contrast, in a related art process, the conventional first hard mask layer has a thickness to allow for the etching of the floating gate in addition to the control gate. Accordingly, in certain embodiments, the first hard mask 150a can have a thickness in the range of about 300 Å to about 1000 Å.

Although the first hard mask layer 150a has a thickness of 1000 Å or more according to the related art, the first hard mask layer 150a may have a thickness of about 500 Å or less according to embodiments of the present invention. Accordingly, the manufacturing cost for the first hard mask layer 150a can be reduced.

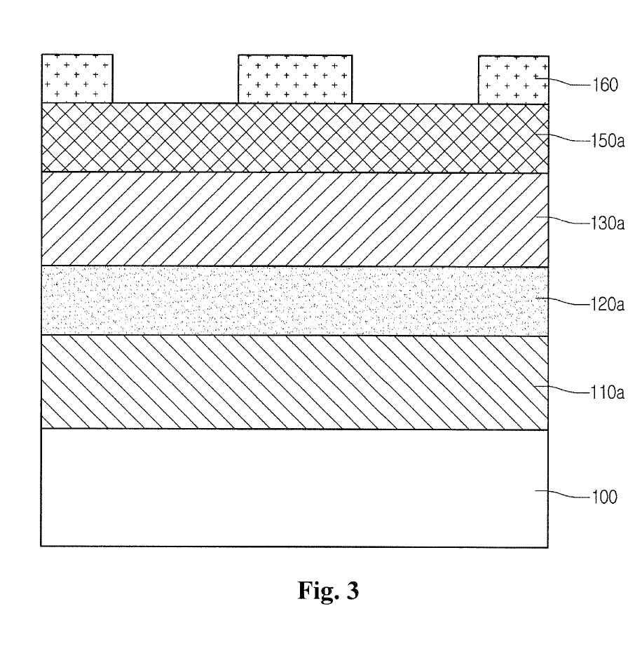

Referring to FIG. 3, a photoresist pattern 160 can be formed on the first hard mask layer 150a.

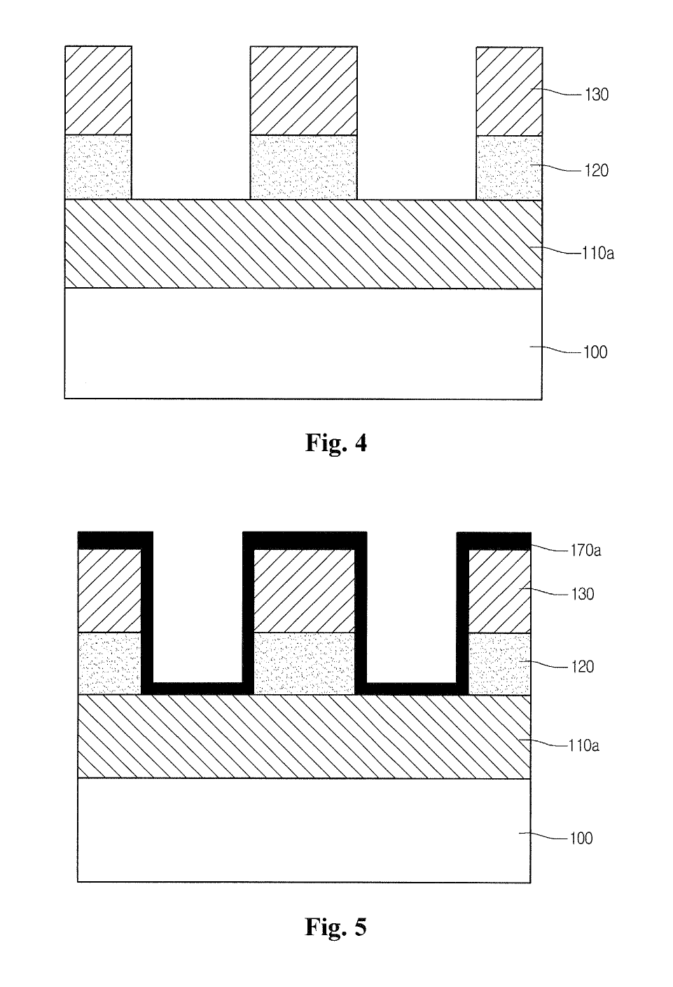

Then, referring to FIG. 4, the first hard mask layer 150a, the second polysilicon layer 130a, and the dielectric layer 120a can be etched by using the photoresist pattern 160 as a mask, thereby forming a control gate electrode 130 and a dielectric layer pattern 120.

A portion of the first polysilicon layer 110a can be exposed in the space between preliminary gate stacks of the control gate electrode 130 and the dielectric layer pattern 120.

Thereafter, the photoresist pattern 160 and the first hard mask layer 150a can be removed.

As shown in FIG. 5, a second hard mask layer 170a can cover the preliminary gate stacks and the exposed portion of the first polysilicon layer 110a.

The second hard mask layer 170a includes a nitride layer.

The second hard mask layer 170a can have a thickness in the range of about 100 Å to about 300 Å. The thickness of the second hard mask layer 170a formed on the top surface of the control gate 130 is thicker than the thickness of the second hard mask layer 170 on the first polysilicon layer 110a.

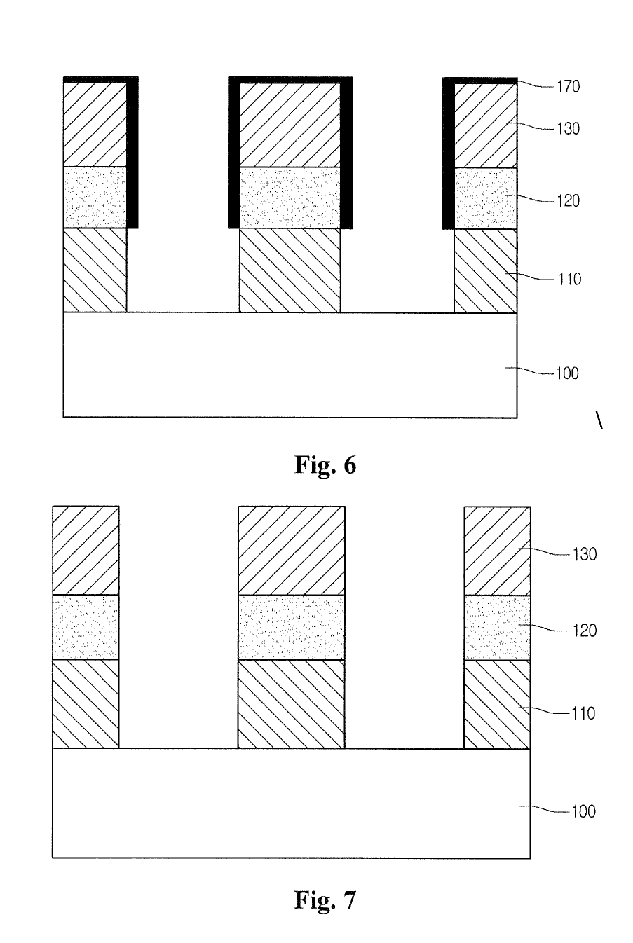

Referring to FIG. 6, the second hard mask layer 170a and the first polysilicon layer 110a can be etched through a dry etch process.

The dry etch process is an anisotropic etch process. In the dry etch process, since etch ions having linearity collides with the semiconductor substrate, the etch ions etch the second hard mask layer 170a on top surfaces of both the control gate electrode 130 and the first polysilicon layer 110a without removing the second hard mask layer 170a on the sidewall of the control gate electrode 130 and the dielectric layer pattern 120. In addition, the second hard mask 170 may not be completely removed from the control gate electrode 130. This can occur because of the thicker thickness of the second hard mask layer 170a on the control gate electrode 130.

The second hard mask layer 170a and the first polysilicon layer 110a between the preliminary gate stacks are etched, thereby forming a floating gate electrode 110. Even though the second hard mask layer 170a thinly remaining on the top surface of the control gate, it can be protected because the etching rate of the polysilicon is higher than the etching rate of the second hard mask 170 during the etching of the floating gate electrode 110.

As shown in FIG. 7, the second hard mask 170 can be removed through a wet etch process.

An etch solution used in the wet etch process can include H₃PO₄, and the wet etch process may be performed for about 90 seconds to about 270 seconds under a temperature in the range of about 100° C. to about 160° C.

After the second hard mask 170 is removed through the wet etch process, the resultant structure may be cleaned by using cleaning solution (NC-2 cleaning solution) for 5 seconds to 20 seconds in order to remove foreign substances including particles.

The cleaning solution can include TMH (TrimethylOxyethylAmmonium-hydroxide, 4% TMH solution), H₂O₂, and H₂O in the ratio of 1:2 to 3:20 to 37.

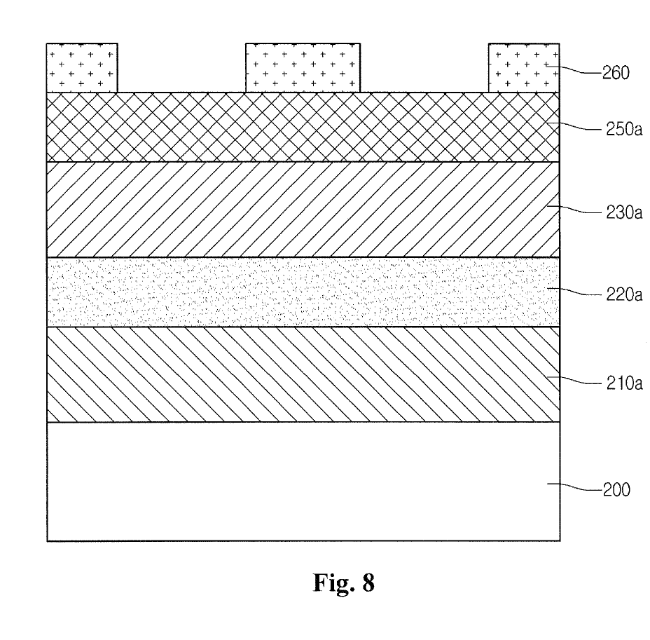

FIGS. 8 to 10 are cross-sectional views showing a method for manufacturing a semiconductor device according to another embodiment.

As shown in FIG. 8, a first polysilicon layer 210a, a dielectric layer 220a, and a second polysilicon layer 230a can be sequentially formed on a semiconductor substrate 200.

A hard mask layer 250a can be formed on the second polysilicon layer 230a, and a photoresist pattern 260 can be formed on the hard mask layer 250a.

The hard mask layer 250a can include a low temperature oxide (LTO) layer.

The LTO layer can be formed through an LP-CVD (Low Pressure Chemical Vapor Deposition) process. The LTO layer can be formed by depositing a mixture of SiH₄ and N₂O under atmosphere of a low pressure and a low temperature of 500° C. or less. For example, the LTO layer may be formed with a thickness in a range of about 500 Å to about 3000 Å by performing the LP-CVD for about 5 seconds to about 120 seconds under a temperature in the range of about 180° C. to about 220° C.

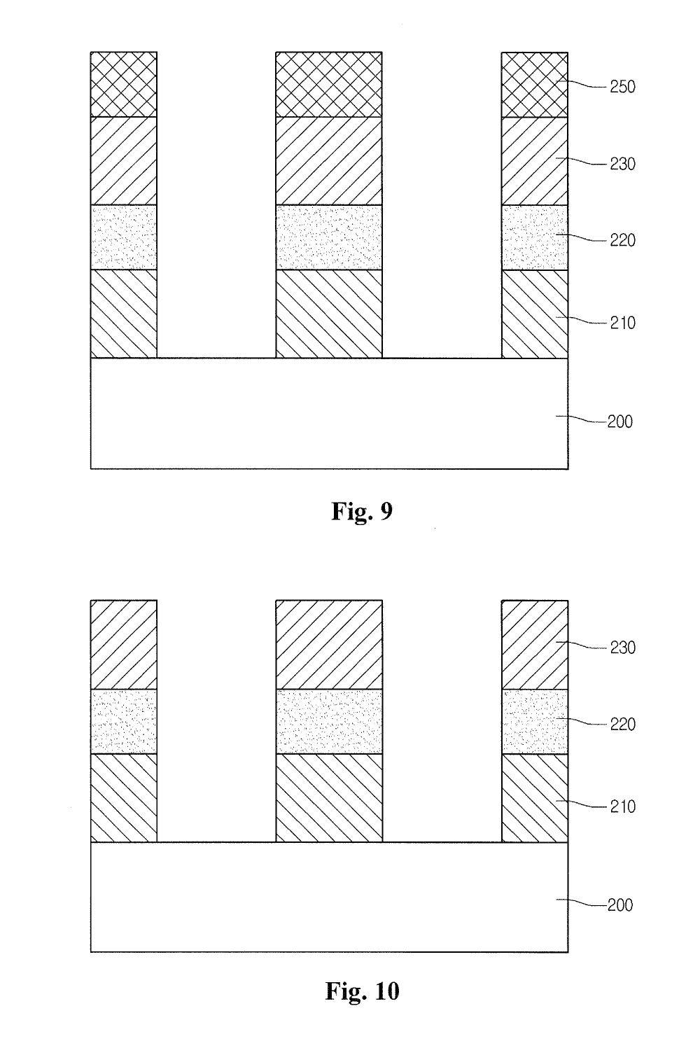

Referring to FIG. 9, hard mask layer 250a can be patterned to form a hard mask 250 by using the photoresist pattern 260 as an etch mask; and the second polysilicon layer 230a, the dielectric layer 220a, and the first polysilicon layer 210a can be etched by using the hard mask 250 as a mask, thereby forming gate stacks including a floating gate electrode 210, a dielectric layer pattern 220, and a control gate electrode 230. Then, referring to FIG. 10, the hard mask 250 can be removed.

The dielectric layer pattern 220 can include a triple structure of an oxide-nitride-oxide layer(ONO) structure.

For example, the dielectric layer 220a can have the ONO structure by forming an oxide layer having a thickness in the range of about 50 Å to about 70 Å through LP-CVD under a temperature in the range of about 700° C. to about 800° C., a nitride layer having a thickness in the range of about 60 Å to about 80 Å through LP-CVD under a temperature in the range of about 650° C. to about 750° C., and an oxide layer having a thickness in the range of about 50 Å to about 70 Å through FTP or LP-CVD under a temperature in the range of about 80° C. to about 900° C.

Since the oxide layer of the dielectric layer pattern 220 has a characteristic different from that of the hard mask 250, the hard mask 250, which can have a porous and soft characteristic, can be easily removed through a wet etch process by increasing etching selectivity for the oxide layer using a DHF (Dilute HF cleaning) solution.

The DHF solution may be obtained by mixing hydrogen fluoride (HF) with deionized water in the ratio of 1:100 to 250.

The time for the wet etch process varies according to a remaining thickness of the hard mask 250.

For example, when the remaining LTO layer has a thickness in the range of about 400 Å to about 1000 Å, the LTO layer may be removed without the damage of the dielectric layer 220 of the gate stack by using the DHF solution for about 50 seconds to about 300 seconds.

Thereafter, a surface treatment of the gate stack and the semiconductor substrate can be performed under a temperature in the range of about 60° C. to about 85° C. through VPC (Vapor Phase Cleaning).

In the VPC, HF can be used.

In the VPC, etching selectivity is increased as a temperature is lowered, particularly, under a temperature in the range of about 30° C. to about 40° C. According to an embodiment, the VPC is performed under a temperature of about 60° C. to about 85° C., so that negative influences with respect to gate patterns can be avoided, and the dielectric layer is not damaged.

Thereafter, the resultant structure can be treated by using a cleaning solution (NC-2) for 5 minutes to 20 minutes in order to remove foreign substances including particles.

The cleaning solution can include TMH (TrimethylOxyethylAmmonium-hydroxide, 4% TMH solution), H₂O₂, and H₂O in the ratio of 1:2 to 3:20 to 37.

In the flash memory device according to an embodiment, a nitride layer, which is used as a hard mask for gate patterning, covers the dielectric layer 220, thereby inhibiting the dielectric layer 220 from being undercut. Accordingly, it is possible to inhibit the characteristics of the flash memory device from being degraded and to improve a yield rate.

According to certain embodiments, the material for the hard mask can be changed, so that it is possible to inhibit the dielectric layer from being damaged without exerting an influence upon the profile of the gate stack. Accordingly, a product yield can be improved, the reliability can be ensured, and the manufacturing process can be simplified.

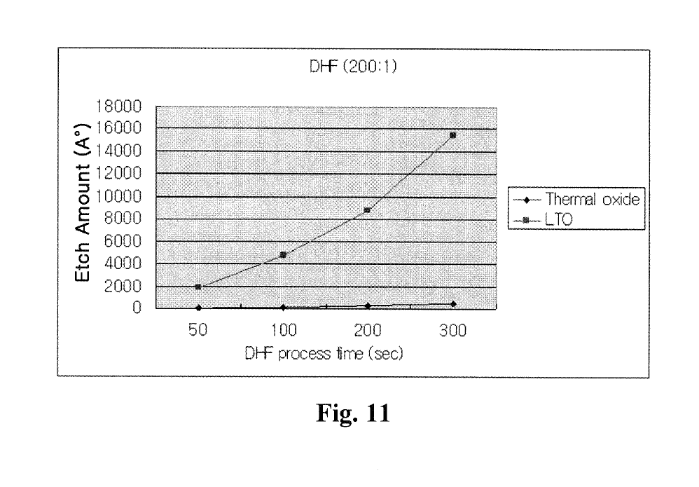

FIG. 11 is a graph showing characteristics of a hard mask that can be used in accordance with an embodiment of the present invention.

FIG. 11 shows the etch rate variation in a TEOS layer that is a thermal oxide used as a hard mask and an LTO layer that is a material of a hard mask according to the embodiment. In this case, the hard mask is removed by using DHF solution obtained by mixing water with hydrogen fluoride in a mixing ratio of 200:1. When taking into consideration the thickness of the hard mask of the LTO layer etched according to a DHF process time, the ONO structure of the dielectric layer 230 is not damaged when the DHF process time is in the range of about 50 seconds to about 300 seconds.

The etch amount of the LTO layer rapidly increases while the etch amount of the TEOS layer is seldom changed.

In other words, when removing a hard mask of the LTO layer, the ONO layer having a characteristic similar to that of the TEOS layer may be rarely damaged.

According to the embodiment, since an LTO layer is used as a hard mask in a gate patterning process, there is no problem related to patterning, and it is possible to inhibit an ONO structure from being damaged. In addition, a photolithography process can be performed by using existing equipment, so that the manufacturing cost can be reduced, and a yield rate and reliability can be improved.

According to embodiments, the patterning failure of a hard mask or the damage of a dielectric layer caused by the reduction of a line width can be inhibited, so that a semiconductor device having a line width of 90 nm or less can be manufactured by using KrF light or ArF light.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, the method comprising:
sequentially forming a floating gate layer, a dielectric layer, a control gate layer, and a first hard mask on a semiconductor substrate;
forming a control gate and a dielectric layer pattern by etching the control gate layer and the dielectric layer using the first hard mask as an etch mask;
forming a second hard mask layer on an entire surface of the semiconductor substrate formed with the control gate and the dielectric layer pattern;
forming a second hard mask by etching the second hard mask layer such that the second hard mask surrounds the control gate and the dielectric layer pattern; and
forming a floating gate by etching the floating gate layer using the second hard mask as an etch mask.

2. The method according to claim 1, wherein the first hard mask comprises an oxide layer, and the second hard mask comprises a nitride layer.

3. The method according to claim 1, wherein the second hard mask has a thickness in a range of about 100 Å to about 300 Å.

4. The method according to claim 1, wherein forming the second hard mask comprises dry-etching the second hard mask layer, so that the second hard mask protects a side surface of the control gate and the dielectric layer pattern while exposing a top surface of the floating gate layer.

5. The method according to claim 1, wherein the dielectric layer has an oxide-nitride-oxide layer (ONO) structure.

6. The method according to claim 1, further comprising removing the second hard mask through performing wet-etching to the second hard mask using an etch solution including H₃PO₄ under a temperature in a range of about 100° C. to about 160° C. for about 90 seconds to about 270 seconds after forming the floating gate.

7. The method according to claim 6, further comprising cleaning the entire surface of the semiconductor substrate using a cleaning solution for about 5 seconds to about 20 seconds, after removing the second hard mask.

8. The method according to claim 7, wherein the cleaning solution comprises TMH (TrimethylOxyethylAmmonium-hydroxide, 4% TMH solution), H₂O₂, and H₂O in the ratio of 1:2˜3:20˜37.

9. A method for manufacturing a semiconductor device, the method comprising:
sequentially forming a floating gate layer, a dielectric layer, and a control gate layer on a semiconductor substrate;
forming an LTO layer on the control gate layer;
forming a hard mask by patterning the LTO layer;
forming a gate stack by etching the control gate layer, the dielectric layer, and the floating gate layer using the hard mask as an etch mask; and
removing the hard mask.

10. The method according to claim 9, wherein forming the LTO layer comprises depositing an oxide layer through LPCVD (Low Pressure Chemical Vapor Deposition) under a temperature in a range of about 180° C. to about 220° C.

11. The method according to claim 9, wherein the LTO layer is formed to a thickness in a range of about 500 Å to about 3000 Å.

12. The method according to claim 9, wherein removing the hard mask comprises using a DHF (Dilute HF cleaning) solution.

13. The method according to claim 12, wherein the DHF solution is obtained by mixing hydrogen fluoride (HF) with deionized water in a ratio of 1 to 100 to 250, and wherein the hard mask is removed by treating the hard mask using the DHF solution for about 50 seconds to about 300 seconds.

14. The method according to claim 9, further comprising treating an entire surface of the semiconductor substrate through VPC (Vapor Phase Cleaning) under a temperature in a range of about 65° C. to about 85° C. after removing the hard mask.

15. The method according to claim 9, further comprising cleaning an entire surface of the semiconductor substrate using a cleaning solution for about 5 seconds to about 20 seconds, after removing the hard mask.

16. The method according to claim 15, wherein the cleaning solution comprises TMH (TrimethylOxyethylAmmonium-hydroxide, 4% TMH solution), H₂O₂, and H₂O in a ratio of 1:2 to 3:20 to 37.
